(19) United States
(12) Patent Application Publication
(10) Pub. No.: US 2026/0075827 A1
(43) Pub. Date: Mar. 12, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventor: Jae Hyun HAN, Icheon-si Gyeonggi-do (KR)

(73) Assignee: SK hynix Inc., Icheon-si Gyeonggi-do (KR)

(21) Appl. No.: 19/061,597

(22) Filed: Feb. 24, 2025

(30) Foreign Application Priority Data
Sep. 12, 2024 (KR) 10-2024-0124650

(51) Int. Cl. H10B 43/35; H10B 43/27

(52) U.S. Cl. CPC H10B 43/35; H10B 43/27

(57) ABSTRACT

A memory device according to an embodiment of the present disclosure includes a stacked structure including conductive layers spaced apart from each other in a first direction, a cell plug extending in the first direction in the stacked structure, and air gaps defined between the conductive layers, wherein the air gaps extend past the conductive layers towards the cell plug.

### CROSS-REFERENCE TO RELATED APPLICATION

The present application claims priority under 35 U.S.C. § 119(a) to Korean patent application number 10-2024-0124650 filed on Sep. 12, 2024, in the Korean Intellectual Property Office, the entire contents of which application is incorporated herein by reference.

### BACKGROUND

### 1. Technical Field

Various embodiments of the present disclosure relate to a memory device and a manufacturing method of the memory device, and more particularly, to a memory device including a memory block having a three-dimensional structure, and a method of manufacturing the memory device.

### 2. Related Art

Memory devices may include non-volatile memory devices that retain stored data even in the absence of power supply. Non-volatile memory devices may be divided into two-dimensionally structured memory devices or three-dimensionally structured memory devices, depending on arrangements of memory cells. Memory cells of a non-volatile memory device having a two-dimensional structure may be arranged in a single layer on a substrate. Memory cells of a non-volatile memory device having a three-dimensional structure may be stacked in a vertical direction to the substrate. Because an integration density of the non-volatile memory device having the three-dimensional structure is greater than that of the non-volatile memory device having the two-dimensional structure, electronic devices including three-dimensionally structured non-volatile memory devices have been increasing.

### SUMMARY

According to an embodiment, a memory device may include a stacked structure including conductive layers spaced apart from each other in a first direction, a cell plug extending in the first direction in the stacked structure, and air gaps defined between the conductive layers, wherein the air gaps extend past the conductive layers towards the cell plug.

According to an embodiment, a method of manufacturing a memory device may include forming a stacked structure including sacrificial layers and interlayer insulating layers, wherein the sacrificial layers and the interlayer insulating layers are stacked alternately with each other in a first direction, forming an opening extending in the first direction in the stacked structure, forming sacrificial patterns on side surfaces of the interlayer insulating layers exposed through the opening, forming a cell plug in the opening in which the sacrificial patterns are formed, replacing the sacrificial layers with conductive layers, and forming air gaps by removing the interlayer insulating layers and the sacrificial patterns.

### BRIEF DESCRIPTION OF THE DRAWINGS

FIG. 1 is a diagram illustrating a memory device according to an embodiment of the present disclosure;

FIG. 2 is a circuit diagram illustrating a memory block according to an embodiment of the present disclosure;

FIG. 3 is a cross-sectional diagram illustrating the structure of a memory device according to an embodiment of the present disclosure;

FIGS. 4A, 4B, 4C, 4D, 4E, and 4F are diagrams illustrating a method of manufacturing a memory device according to an embodiment of the present disclosure;

FIGS. 5A, 5B, and 5C are diagrams illustrating a structure of a memory device according to an embodiment of the present disclosure;

FIG. 6 is a diagram illustrating a memory card system to which a memory device according to an embodiment of the present disclosure is applied; and

FIG. 7 is a diagram illustrating a solid state drive (SSD) system to which a memory device according to an embodiment of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, examples of embodiments of the present disclosure will be described in detail with reference to the accompanying drawings in order for those skilled in the art to be able to readily implement the technical spirit of the present disclosure.

Various embodiments of the present disclosure provide a memory device capable of improving operating performance by improving a structure of a stacked structure and a method of manufacturing the memory device.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout.

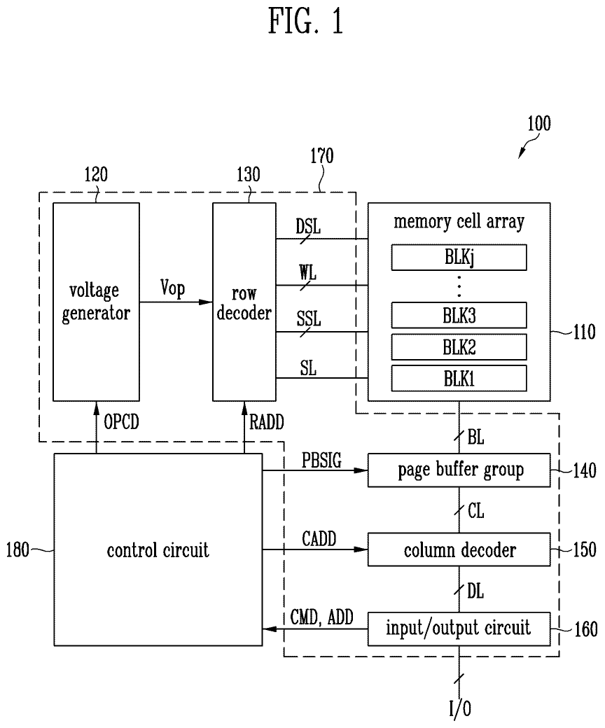

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to jth memory blocks BLK1 to BLKj. The first to jth memory blocks BLK1 to BLKj may have a three-dimensional structure. The three-dimensionally structured first to jth memory blocks BLK1 to BLKj may include memory cells which are stacked in a vertical direction to a substrate.

Memory cells may store one or more bits of data according to a program method. For example, a method of storing one bit in a single memory cell is referred to as a single-level cell method, and a method of storing two bits of data is referred to as a multi-level cell. A method of storing three bits of data in a single memory cell is referred to as a triple-level cell method. A method of storing four bits of data is referred to as a quad level cell method.

The peripheral circuit 170 may include a program operation for storing data in the memory cell array 110, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop applied to perform a program operation, a read operation, or an erase operation in response to an operating code OPCD. For example, the voltage generator 120 may generate program voltages, pass voltages, turn-on voltages, turn-off voltages, a ground voltage, negative voltages, source voltages, verify voltages, read voltages, erase voltages, and precharge voltages in response to the operating code OPCD.

Program voltages may be applied to a selected word line among word lines WL during a program operation and may be used to increase threshold voltages of memory cells coupled to the selected word line. Pass voltages may be applied to unselected word lines among the word lines WL during a program or read operation and may be used to turn on memory cells coupled to the unselected word lines.

Turn-on voltages may be applied to drain select lines DSL or source select lines SSL and may be used to turn on drain select transistors or source select transistors. Turn-off voltages may be applied to the drain select lines DSL or the source select lines SSL and may be used to turn off the drain select transistors or the source select transistors.

A ground voltage may be 0 V. Negative voltages may be lower than 0 V. Source voltages may be applied to a source line SL and may be a negative voltage, a ground voltage, or a positive voltage. Verify voltages may be used for determining threshold voltages of selected memory cells during a program or erase operation and may be applied to the selected word line or all word lines coupled to the selected memory block.

Read voltages may be applied to the selected word line during a read operation and used to determine data stored in the memory cells. Erase voltages may be applied to the source line SL during an erase operation and used for lowering the threshold voltages of the memory cells. A precharge voltage may be a positive voltage for precharging a channel of unselected strings during a verify or read operation and may be supplied to the source line SL.

The row decoder 130 may be coupled to the voltage generator 120 through global lines and to the first to jth memory blocks BLK1 to BLKj through drain select lines DSL, the word lines WL, source select lines SSL, and the source line SL. The row decoder 130 may be configured to apply the operating voltages Vop to the drain select lines DSL, the word lines WL, the source select lines SSL, and the source line SL which are coupled to the selected memory block according to a row address RADD.

The page buffer group 140 may include page buffers (not shown) which are commonly coupled to the first to jth memory blocks BLK1 to BLKj. For example, each of the page buffers (not shown) may be coupled to the first to jth memory blocks BLK1 to BLKj through bit lines BL. The page buffers (not shown) may sense currents or voltages in the bit lines BL in response to page buffer control signals PBSIG.

The column decoder 150 may transfer data between the page buffer group 140 and the input/output circuit 160 in response to a column address CADD. For example, the column decoder 150 may be coupled to the page buffer group 140 through column lines CL and the input/output circuit 160 through data lines DL.

The input/output circuit 160 may receive or output a command CMD, an address ADD and data through input/output lines I/O. For example, the input/output circuit 160 may transfer the command CMD and the address ADD, which are received from an external device through the input/output lines I/O, to the control circuit 180, and may transfer the data, which is received from an external controller through the input/output lines I/O, to the column decoder 150. Alternatively, the input/output circuit 160 may output the data, which is transferred from the column decoder 150, to the external controller through the input/output lines I/O.

The control circuit 180 may output the operating code OPCD, the row address RADD, the page buffer control signals PBSIG, and the column address CADD in response to the command CMD and the address ADD. For example, when the command CMD which is input to the control circuit 180 corresponds to a program operation, the control circuit 180 may control the peripheral circuit 170 to perform a program operation of the selected memory block by the address ADD. When the command CMD which is input to the control circuit 180 corresponds to a read operation, the control circuit 180 may control the peripheral circuit 170 to perform the read operation of the selected memory block by the address and output the read data. When the command CMD which is input to the control circuit 180 corresponds to an erase operation, the control circuit 180 may control the peripheral circuit 170 to perform the erase operation of the selected memory block.

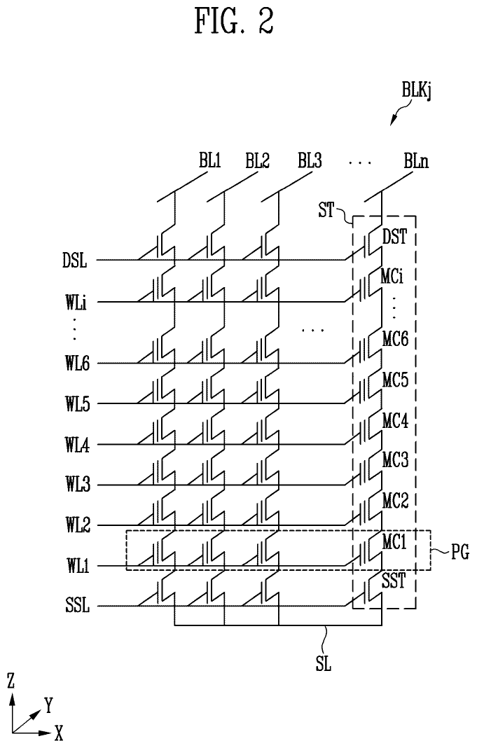

FIG. 2 is a circuit diagram illustrating the jth memory block BLKj according to an embodiment of the present disclosure.

The first to jth memory blocks BLK1 to BLKj as shown in FIG. 1 may have the same configuration as each other. FIG. 2 shows the jth memory block BLKj as an example among the first to jth memory blocks BLK1 to BLKj.

Referring to FIG. 2, the jth memory block BLKj may include strings ST that couple first to nth bit lines BL1 to BLn and the source line SL. The first to nth bit lines BL1 to BLn may extend in a Y direction and be spaced apart from each other in an X direction. Thus, the strings ST which extend in a Z direction may be spaced apart from each other in the X and Y directions.

One of the strings ST which are coupled to the nth bit line BLn is described as an example. The string ST may include a source select transistor SST, first to ith memory cells MC1 to MCi, and a drain select transistor DST. The jth memory block BLKj as shown in FIG. 2 is provided for schematically illustrating the connection configuration of the jth memory block BLKj. Thus, the number of source select transistors SST, the number of first to ith memory cells MC1 to MCi, and the number of drain select transistors DST which are included in each of the strings ST may vary depending on respective memory devices. For example, the string ST may include two or more source select transistors SST or two or more drain select transistors DST.

Gates of the source select transistors SST included in different cell strings ST may be coupled to the source select lines SSL. Gates of the first to ith memory cells MC1 to MCi may be coupled to first to ith word lines WL1 to WLi. Gates of the drain select transistors DST may be coupled to the drain select lines DSL.

Memory cells formed on the same layer among the first to ith memory cells MC1 to MCi may be coupled to the same word line. For example, the first memory cells MC1 included in different strings ST may be commonly coupled to the first word line WL1 and the ith word line WLi, and the ith memory cells MCi included in different strings ST may be commonly coupled to the ith word line WLi. A group of memory cells which are included in different strings ST and coupled to the same word line may constitute a page PG. Program and read operations may be performed in units of pages PG, and an erase operation may be performed in units of memory blocks.

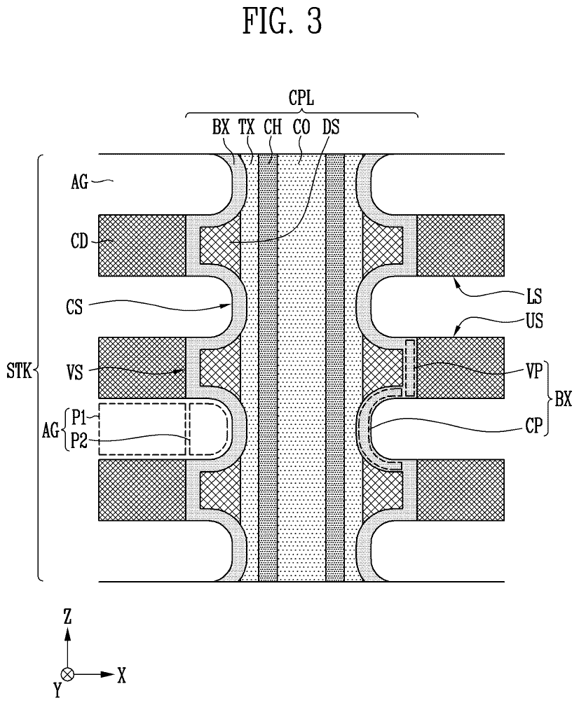

FIG. 3 is a cross-sectional diagram illustrating the structure of a memory device according to an embodiment of the present disclosure.

A cell plug CPL shown in FIG. 3 may correspond to a portion of any one string ST included in one of the first to jth memory blocks BLK1 to BLKj as shown in FIG. 1. For example, the source select transistor SST, the first to ith memory cells MC1 to MCi, and the drain select transistor DST as described above with reference to FIG. 2 may be formed at intersections between the cell plug CPL and conductive layers CD.

Referring to FIG. 3, the memory device may include a stacked structure STK which includes the conductive layer CD. The stacked structure STK may include the conductive layers CD which are separated from each other in the Z direction. Each of the conductive layer CD may extend in the X direction and the Y direction. The conductive layer CD may correspond to the drain select lines DSL, the word lines WL, and the source select lines SSL as described above with reference to FIGS. 1 and 2. The conductive layers CD may include a conductive material. For example, the conductive layers CD may include at least one of tungsten (W), cobalt (Co), nickel (Ni), molybdenum (Mo), silicon (Si), and polysilicon (poly-Si). However, the number of conductive layers CD as shown in FIG. 3 is a mere example, and is not limited to that shown in FIG. 3.

The memory device may include the cell plug CPL. The cell plug CPL may extend in the Z direction in the stacked structure STK. The cell plug CPL may pass through the conductive layers CD. The cell plug CPL may include concave portions which are inwardly recessed toward the center of the cell plug CPL. A side surface of the cell plug CPL may include concave surfaces CS and vertical surfaces VS. The concave surfaces CS and the vertical surfaces VS may be arranged alternately with each other in the Z direction. The conductive layers CD may contact the vertical surfaces VS of the cell plug CPL, respectively.

Air gaps AG may be interposed between the conductive layers CD. That is, the air gaps AG may be located between the conductive layers CD. For example, each of the air gaps AG may be defined by an upper surface US and a lower surface LS of adjacent conductive layers CD. The air gaps AG may refer to substantially empty spaces provided between the conductive layers CD.

The air gaps AG may extend past the conductive layers CD towards the cell plug CPL in the X direction. The air gaps AG may protrude in a horizontal direction more than side surfaces of the conductive layers CD. For example, the air gaps AG may be defined by the concave surfaces CS of the cell plugs CPL.

Each of the air gaps AG may include a first portion P1 which is located between the conductive layers CD. Each of the first portions P1 may be defined by the upper surface US and the lower surface LS of the conductive layers CD which are adjacent to each other in the Z direction. Each of the first portions P1 may be surrounded by the upper surface US and the lower surface LS of the neighboring conductive layers CD. The first portions P1 may overlap the conductive layers CD in the Z direction. The first portions P1 may correspond to space between the separate conductive layers CD. The first portions P1 may extend in the X direction and the Y direction.

Each of the air gaps AG may include a second portion P2 which extends from the first portion P1. Each of the second portions P2 may be defined by a side surface of the cell plug CPL. For example, the second portion P2 may be defined by each of the concave surfaces CS of the cell plug CPL. Each of the second portions P2 may define the cell plug CPL in the Z direction. A height of the second portions P2, for example, a length of the second portion P2 in the Z direction may decrease toward the center of the cell plug CPL. The side surface of each of the second portions P2 may have a round curved shape toward the center of the cell plug CPL.

In the present disclosure, a description is made based on the first portion P1 and the second portion P2 of the air gap AG which are distinct from each other. However, there may be no boundaries between the first portion P1 and the second portion P2, or any boundaries might not be observed therebetween.

The cell plug CPL may include a blocking layer BX. The blocking layer BX may form an outer surface of the cell plug CPL. The blocking layer BX may contact the side surfaces of the conductive layers CD. The blocking layer BX may contact the air gaps AG. The blocking layer BX may include an insulating material. In addition, the blocking layer BX may include an oxide layer. For example, the blocking layer BX may include a silicon oxide layer, a silicon oxynitride layer, or an oxide material corresponding thereto. The blocking layer BX may include a high-k material.

The blocking layer BX may include vertical portions VP which contact the side surfaces of the conductive layers CD, respectively. The vertical portions VP may extend in the Z direction.

In addition, the blocking layer BX may include concave portions CP which are inwardly recessed toward the center of the cell plug CPL between the conductive layers CD. The concave portions CP may have a round shape toward the center of the cell plug CPL. An outer side surface and an inner side surface of each of the concave portions CP may be curved surfaces. The concave portions CP may contact a tunneling layer TX. The concave portions CP may protrude toward the center of the channel layer CH more than the vertical portions VP. The second portions P2 of the air gaps AG may be surrounded by the concave portions CP of the blocking layer BX, respectively.

The vertical portions VP and the concave portions CP of the blocking layer BX may be arranged alternately with each other in the Z direction. The vertical portions VP and the concave portions CP may extend with respect to each other. The blocking layer BX may include an uneven structure. Outer surfaces of the concave portions CP of the blocking layer BX may be the concave surfaces CS of the cell plug CPL. Outer surfaces of the vertical portions VP of the blocking layer BX may be the vertical surfaces VS of the cell plug CPL. For convenience of explanation, in the present disclosure, the vertical portions VP and the concave portions CP are shown to be distinct from each other. However, there may be no boundaries between the vertical portions VP and the concave portions CP, or any boundaries might not be observed therebetween.

The cell plug CPL may include data storage patterns DS. The data storage patterns DS may be spaced apart from each other in the Z direction. The data storage patterns DS may be separated from each other by the air gaps AG. For example, the air gaps AG and the blocking layer BX may be located between the data storage patterns DS which are adjacent to each other in the Z direction. Because the data storage patterns DS formed on different layers are not coupled to each other and are separated from each other, negative charges trapped in the data storage patterns DS might not move to other adjacent data storage patterns DS in the vertical direction during a program operation. In an embodiment, retention characteristics of the memory device may be improved by the data storage patterns DS separated from each other in the Z direction, so that the reliability of the memory device may be improved.

Each of the data storage patterns DS may be located in the X direction with respect to each of the conductive layers CD. The data storage patterns DS may be located at the same level as the conductive layers CD. The data storage patterns DS may be surrounded by the conductive layers CD, respectively. In an embodiment, at least a portion of each of the data storage patterns DS are located at the same level as the conductive layers CD, respectively. For example, as shown in FIG. 3, at least a portion of each of the data storage patterns DS are located at the same level as the conductive layers CD, respectively.

The data storage patterns DS may be disposed between the concave portions CP of the blocking layer BX. The data storage patterns DS may contact the vertical portions VP of the blocking layer BX, respectively. The data storage patterns DS may fill irregular portions formed in the blocking layer BX between the air gaps AG.

The data storage patterns DS may include a nitride layer. For example, the data storage patterns DS may include a silicon nitride layer.

The cell plug CPL may include a tunneling layer TX which contacts the data storage patterns DS and the blocking layer BX. The tunneling layer TX may contact the data storage patterns DS at levels corresponding to the conductive layers CD. In addition, the tunneling layer TX may contact the blocking layer BX at levels corresponding to the air gaps AG. The tunneling layer TX may pass through the conductive layers CD. The tunneling layer TX may extend in the Z direction. The tunneling layer TX may include an insulating material. For example, the tunneling layer TX may include an oxide layer. The tunneling layer TX may include a silicon oxide layer or an oxide material corresponding thereto.

The cell plug CPL may include a channel layer CH which contacts an inner surface of the tunneling layer TX. The tunneling layer TX may pass through the conductive layers CD. The tunneling layer TX may extend in the Z direction. The channel layer CH may be surrounded by the tunneling layer TX. The channel layer CH may include an undoped silicon layer or a doped silicon layer.

The cell plug CPL may include a core pillar CO which fills the inside of the channel layer CH. The core pillar CO may be surrounded by the channel layer CH. The core pillar CO may pass through the conductive layers CD. The core pillar CO may extend in the Z direction. The core pillar CO may include an insulating layer or a conductive layer.

Though not shown, the cell plug CPL may further include a capping layer which is formed on the core pillar CO. The capping layer may contact the channel layer CH on the core pillar CO. The capping layer may include an undoped silicon layer or a doped silicon layer.

According to an embodiment of the present disclosure, the air gaps AG may be formed between the conductive layers CD, so that parasitic capacitance between the conductive layers CD may be reduced. In an embodiment of the present disclosure, because the air gaps AG extend toward the center of the cell plug CPL, the volume of the air gaps AG may be increased more to thereby reduce the parasitic capacitance between the conductive layers CD. In an embodiment, the air gaps AG which extend past the conductive layers CD towards the cell plug CPL in the X direction and may reduce the parasitic capacitance between the conductive layers CD and the channel layer CH.

According to an embodiment of the present disclosure, the air gaps AG may include the second portions P2 which have a round cross section toward the center of the cell plug CPL. In addition, the blocking layer BX may include the concave portions CP having a round shape. The round shape of the concave portions CP of the blocking layer BX may result in increase of the control over the channel layer CH or the memory cells (the first to ith memory cells MC1 to MCi) by the conductive layers CD.

Accordingly, according to an embodiment of the present disclosure, the operating performance of the memory device may be enhanced by improving the structure of the stacked structure STK.

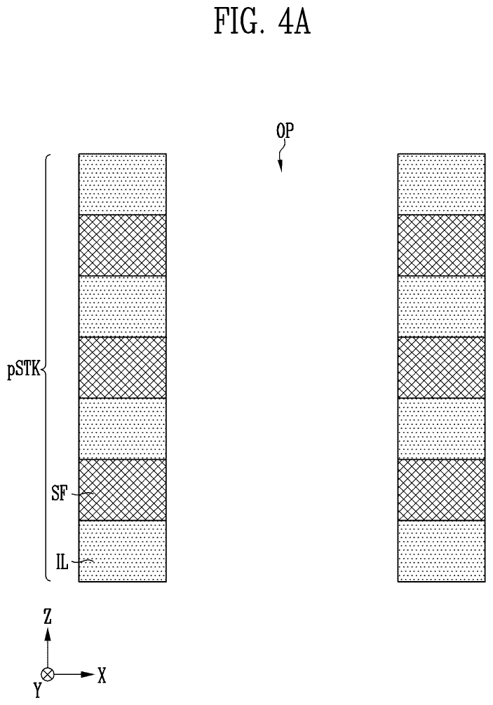

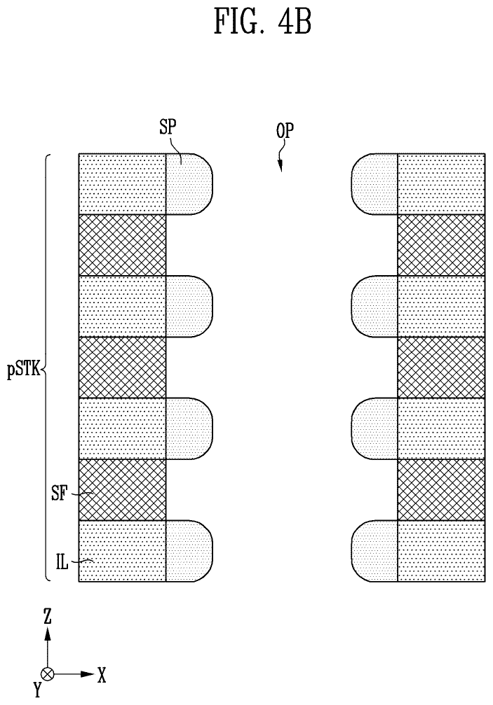

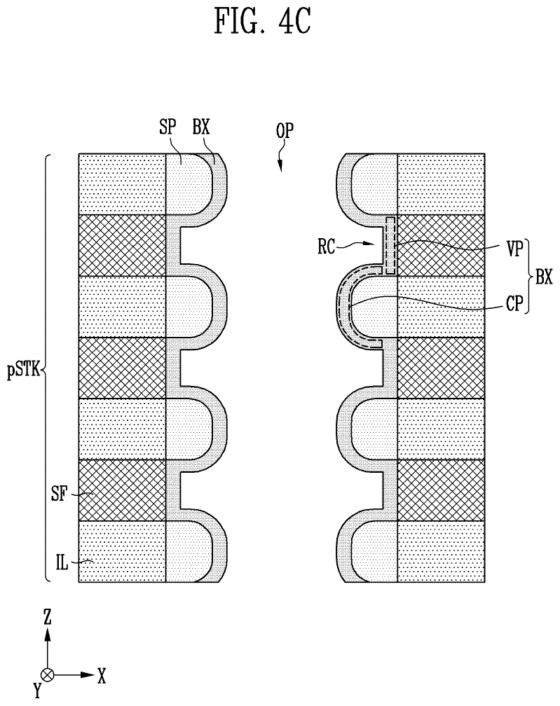

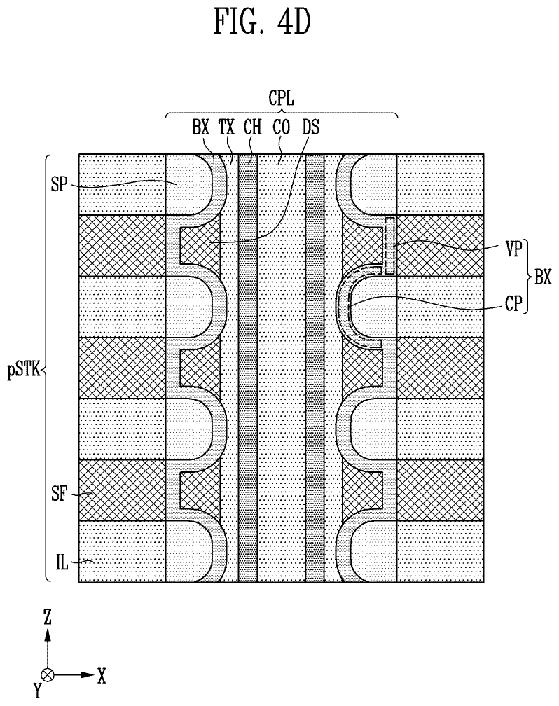

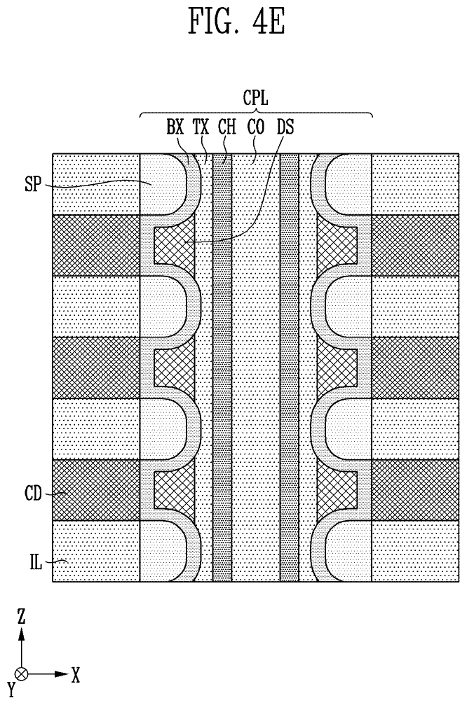

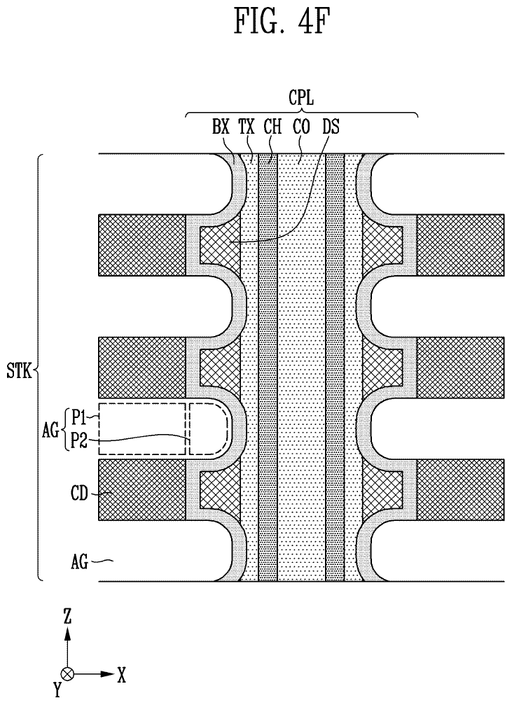

FIGS. 4A to 4F are diagrams illustrating a method of manufacturing a memory device according to an embodiment of the present disclosure.

Referring to FIG. 4A, a preliminary stack structure pSTK which includes sacrificial layers SF and interlayer insulating layers IL may be formed. The sacrificial layers SF and the interlayer insulating layers IL may be alternately stacked with each other in the Z direction.

Each of the interlayer insulating layers IL may include an insulating material. For example, the interlayer insulating layers IL may include an oxide layer. The interlayer insulating layers IL may include a silicon oxide layer or an oxide material corresponding thereto. The sacrificial layers SF may include a material which is selectively removed during subsequent processes. Thus, the sacrificial layers SF may have a different etch selectivity from the interlayer insulating layers IL. The sacrificial layers SF may include a nitride material. For example, the sacrificial layers SF may include a silicon nitride layer.

Subsequently, an opening OP which extends in the Z direction may be formed in the preliminary stack structure pSTK. The opening OP may pass through the sacrificial layers SF and the interlayer insulating layers IL. The opening OP may be in the shape of a hole which extends in the Z direction. Side surfaces of the sacrificial layers SF and the interlayer insulating layers IL may be exposed through a side surface of the opening OP.

Referring to FIG. 4B, sacrificial patterns SP may be formed on the interlayer insulating layers IL which are exposed through the opening OP. The sacrificial patterns SP may be selectively deposited on side surfaces of the interlayer insulating layers IL. For example, the sacrificial patterns SP may grow from surfaces of the interlayer insulating layers IL. The sacrificial patterns SP may include an insulating material. The sacrificial patterns SP may include the same kind of material as the interlayer insulating layers IL. For example, the sacrificial patterns SP may include an oxide layer. The sacrificial patterns SP may include a silicon oxide layer and an oxide material corresponding thereto.

The sacrificial patterns SP may vertically protrude from the side surfaces of the interlayer insulating layers IL in a horizontal direction. An inner surface of each of the sacrificial patterns SP may be a round surface toward the center of the opening OP. In addition, the inner surface of each of the sacrificial patterns SP may be a convex surface toward the center of the opening OP. The height of each of the sacrificial patterns SP (e.g., a length in the Z direction) may increase toward the interlayer insulating layer IL. Outer surfaces of the sacrificial patterns SP may contact the interlayer insulating layers IL. In addition, the outer surfaces of the sacrificial patterns SP may extend in the Z direction. Each of the sacrificial patterns SP may have a ring shape. The sacrificial patterns SP may be spaced apart from each other in the Z direction.

Referring to FIG. 4C, the blocking layer BX may be formed on the sacrificial layers SF and the sacrificial patterns SP. The blocking layer BX may extend on the sacrificial layers SF and the sacrificial patterns SP. The blocking layer BX may be conformally formed on the sacrificial layers SF and the sacrificial patterns SP. The blocking layer BX may include a high-k material.

Because the sacrificial patterns SP protrude from the interlayer insulating layers IL, the blocking layer BX may have an uneven structure which is defined by surfaces of the sacrificial patterns SP and the sacrificial layers SF. The blocking layer BX may include the vertical portions VP which contact the sacrificial patterns SF, respectively, and the concave portions CP which contact the sacrificial patterns SP, respectively. The vertical portions VP may extend in the Z direction. The concave portions CP may surround the sacrificial patterns SP, respectively. The blocking layer BX may include recesses RC between the sacrificial patterns SP sequentially arranged in the Z direction.

Referring to FIG. 4D, the data storage patterns DS may be formed in the opening OP. The data storage patterns DS may be spaced apart from each other in the Z direction. For example, the data storage patterns DS may be formed between the consecutive sacrificial patterns SP in the Z direction. The data storage patterns DS may be separated from each other in the Z direction by the sacrificial patterns SP and the blocking layer BX. Each of the data storage patterns DS may have a ring shape. The concave portion C of the blocking layer BX and any one of the sacrificial patterns SP may be formed between the data storage patterns DS which are adjacent to each other in the Z direction.

Each of the data storage patterns DS may be disposed between the concave portions CP of the blocking layer BX. The data storage patterns DS may contact the vertical portions VP of the blocking layer BX. The data storage patterns DS may be located in a horizontal direction of the sacrificial layers SF.

Recesses included in the blocking layer BX, such as the recesses RC in FIG. 4C, may be filled with the data storage patterns DS, respectively. For example, a data storage material may fill the recesses RC in FIG. 4C of the blocking layer BX. The data storage material may include a nitride layer. The data storage material may cover the entire surface of the blocking layer BX. Subsequently, the data storage material may be removed from a lower part of the opening OP and a side surface of the blocking layer BX. A dry etch process may be performed to remove a portion of the data storage material. For example, anisotropic dry etching may be performed such that the data storage material may remain in the recesses RC of FIG. 4C of the blocking layer BX. In the anisotropic dry etching, a source gas having higher etch selectivity with respect to the data storage material than the blocking layer BX may be used. The data storage material remaining in the recesses RC of FIG. 4C may be the data storage patterns DS.

Subsequently, the tunneling layer TX, the channel layer CH, and the core pillar CO may be sequentially formed in the opening OP. The tunneling layer TX may contact the data storage patterns DS and the blocking layer BX in the opening OP. The tunneling layer TX may contact at least a portion of each of the concave portions CP of the blocking layers BX. The tunneling layer TX may be conformally formed on the side surfaces of the data storage patterns DS and the blocking layer BX. The channel layer CH may contact an inner surface of the tunneling layer TX. The channel layer CH may be conformally formed on the side surface of the tunneling layer TX. The core pillar CO may contact an inner surface of the channel layer CH and fill the opening OP. The blocking layer BX, the data storage patterns DS, the tunneling layer TX, the channel layer CH, and the core pillar CO may form the cell plug CPL. However, the structure and shape of the cell plug CPL might not be limited to those shown in FIG. 4D. For example, a capping layer may be further formed on the core pillar CO. In addition, the shape of the blocking layer BX may vary depending on the shape of the sacrificial patterns SP. The tunneling layer TX may include an oxide layer. The channel layer CH may include a doped silicon layer or an undoped silicon layer. The core pillar CO may include an insulating layer or a conductive layer.

Referring to FIG. 4E, the sacrificial layers SF may be replaced by the conductive layers CD. For example, an etch process may be performed to remove the sacrificial layers SF. Because the sacrificial layers SF are formed between the interlayer insulating layers IL, isotropic dry etching or wet etching may be performed as the etch process. Because the sacrificial layers SF are removed, empty spaces may be formed between the interlayer insulating layers IL. The conductive layer CD may be formed in those spaces. The conductive layers CD may include at least one of tungsten (W), cobalt (Co), nickel (Ni), molybdenum (Mo), silicon (Si), and polysilicon (Poly-Si). In addition, other various conductive layers may be formed.

Referring to FIG. 4F, the interlayer insulating layers IL and the sacrificial patterns SP may be removed to form the air gaps AG. Isotropic wet etching may be performed so as to selectively etch the interlayer insulating layers IL and the sacrificial patterns SP. Spaces from which the interlayer insulating layers IL are removed may correspond to the first portions P1 of the air gaps AG. The first portions P1 may be located between the conductive layers CD. Spaces from which the sacrificial patterns SP are removed may correspond to the second portions P2 of the air gaps AG. The second portions P2 may extend past the conductive layers CD towards the cell plug CPL, from the first portions P1, in the X direction. The conductive layers CD which are separated from each other by the air gaps AG may form the stacked structure STK.

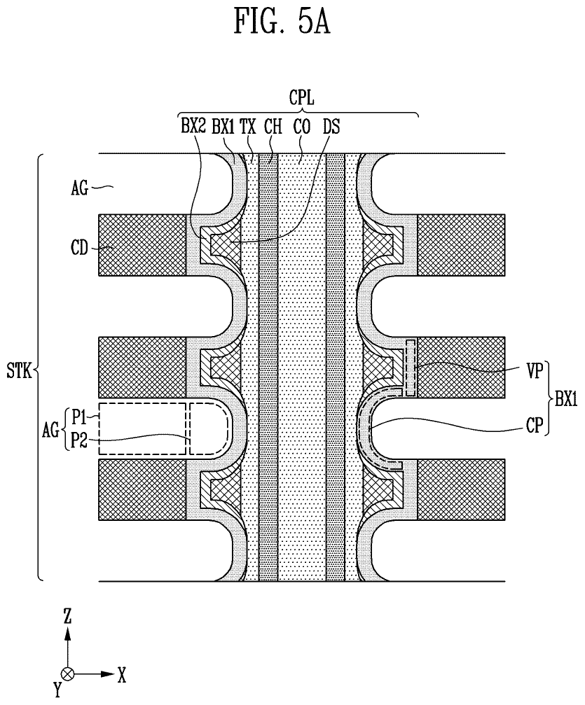

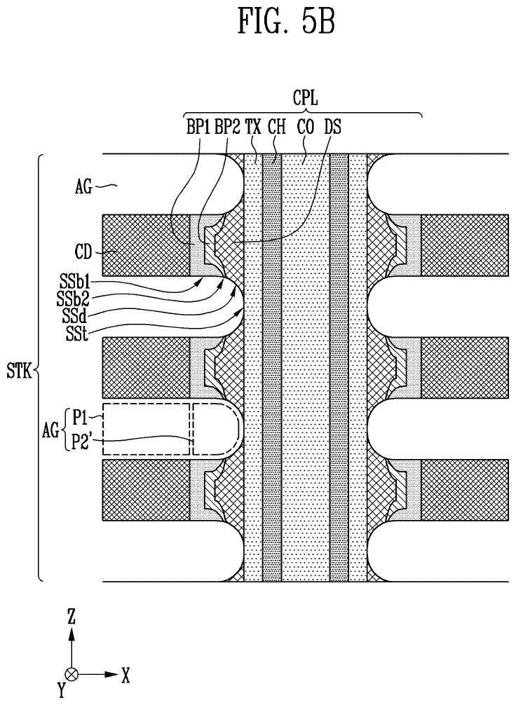

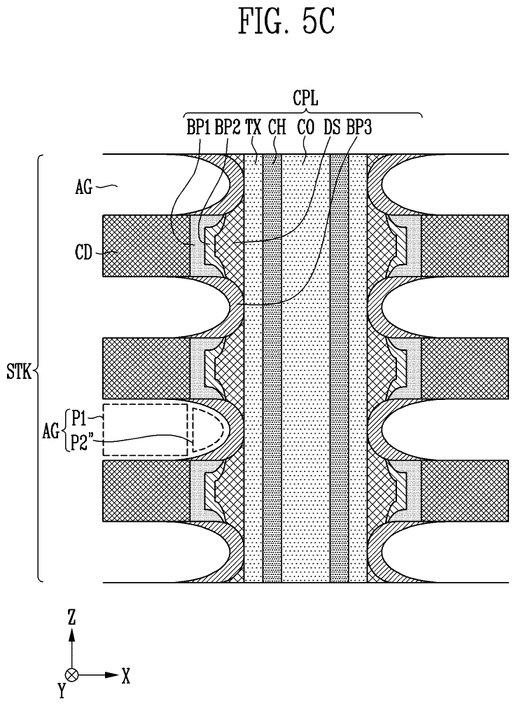

FIGS. 5A to 5C are diagrams illustrating a structure of a memory device according to an embodiment of the present disclosure.

FIGS. 5A to 5C illustrate other embodiments with some changes to the configuration of the embodiment of the cell plug CPL as in shown in FIG. 3. In connection with FIGS. 5A to 5C, a description of the overlapping portions of the configuration of the cell plug CPL shown in FIG. 3 will be briefly described or omitted.

Referring to FIG. 5A, the cell plug CPL may include a first blocking layer BX1 which contacts side surfaces of the conductive layers CD. The first blocking layer BX1 may correspond to the blocking layer BX as shown in FIG. 3. The first blocking layer BX1 may include the vertical portions VP and the concave portions CP. The second portions P2 of the air gaps AG may be surrounded by the concave portions CP of the first blocking layer BX1, respectively. The second portions P2 of the air gaps AG may be defined by an outer side surface of the first blocking layer BX1. The first portions P1 of the air gaps AG may be defined by lower and upper surfaces of the conductive layers CD.

The cell plug CPL may include a second blocking layer BX2 which contacts at least a portion of an inner surface of the first blocking layer BX1. The second blocking layer BX2 may be formed on at least a portion of the inner surface of the first blocking layer BX1. For example, the second blocking layer BX2 may be formed on the inner surfaces of the vertical portions VP of the first blocking layer BX1. In addition, the second blocking layer BX2 may be formed on at least a portion of inner surfaces of the concave portions CP of the first blocking layer BX1. The second blocking layer BX2 may extend on the inner surface of the first blocking layer BX between the air gaps AG. The second blocking layer BX2 may include a high-k material. The second blocking layer BX2 may include the same kind of material as the first blocking layer BX1.

The second blocking layer BX2 may extend in the Z direction on the first blocking layer BX1. Alternatively, the second blocking layer BX2 may be separated from the first blocking layer BX1 in the Z direction. An inner surface of the first blocking layer BX1 may be completely covered by the second blocking layer BX2, or a portion of the inner surface of the first blocking layer BX1 may be exposed and contact the tunneling layer TX.

The cell plug CPL may include the data storage patterns DS which are surrounded by the second blocking layer BX2. The data storage patterns DS may contact the second blocking layer BX2. The data storage patterns DS may be separated from the first blocking layer BX1 by the second blocking layer BX2.

Because an embodiment of FIG. 5A further includes the second blocking layer BX2 in addition to the embodiment of FIG. 3, blocking performance of the cell plug CPL may be improved.

Referring to FIG. 5B, the cell plug CPL may include first blocking patterns BP1. The first blocking patterns BP1 may be spaced apart from each other in the Z direction. The first blocking patterns BP1 may be separated from each other in the Z direction by the air gaps AG. The first blocking patterns BP1 may contact side surfaces of the conductive layers CD. The first blocking patterns BP1 may surround second portions P2′ of the air gaps AG. Surface SSb1 of the first blocking patterns BP1 may be exposed by the second portions P2′ of the air gaps AG.

The cell plug CPL may include second blocking patterns BP2. The second blocking patterns BP2 may be spaced apart from each other in the Z direction. The second blocking patterns BP2 may be separated from each other in the Z direction by the air gaps AG. The second blocking patterns BP2 may contact inner surfaces of the first blocking patterns BP1, respectively. The second blocking patterns BP2 may surround the second portions P2′ of the air gaps AG. Surfaces SSb2 of the second blocking patterns BP2 may be exposed by the second portions P2′ of the air gaps AG. However, contrary to FIG. 5B, the second blocking patterns BP2 might not contact the second portions P2′.

The first blocking patterns BP1 and the second blocking patterns BP2 may include a high-k material. The first blocking patterns BP1 and the second blocking patterns BP2 may include the same or similar material.

The cell plug CPL may include the data storage patterns DS which are separated from each other in the Z direction. The data storage patterns DS may be separated from each other in the Z direction by the air gaps AG. The second blocking patterns DS may contact inner surfaces of the second blocking patterns BP2, respectively. The data storage patterns DS may surround the second portions P2′ of the air gaps AG. Surfaces SSd of the data storage patterns DS may be exposed by the second portions P2′ of the air gaps AG.

However, apart from various embodiments of FIGS. 3 and 5A, the data storage patterns DS may be exposed through the air gaps AG. As shown in FIG. 5B, as compared to various embodiments of FIG. 5A, portions of the first and second blocking layers BX1 and BX2 may be removed to form the first and second blocking patterns BP1 and BP2. A volume of each of the data storage patterns DS may be increased as much as space from which the portions of the first and second blocking patterns BP1 and BP2 are removed.

The tunneling layer TX may contact inner surfaces of the data storage patterns DS. The tunneling layer TX may be separated from the first and second blocking patterns BP1 and BP2 by the data storage patterns DS. The tunneling layer TX may surround the second portions P2′ of the air gaps AG. A surface SSt of the tunneling layer TX may be exposed by the second portions P2′ of the air gaps AG.

Though not shown, referring to FIGS. 4C and 5B, a first blocking layer may be formed on the sacrificial layers SF and the sacrificial patterns SP, and a portion of the first blocking layer located on the sacrificial patterns SP may be removed to form the first blocking patterns BP1. In addition, a second blocking layer may be formed on the sacrificial patterns SP and the first blocking patterns BP1, and a portion of the second blocking layer located on the sacrificial patterns SP may be removed to form the second blocking patterns BP2. Subsequently, the data storage patterns DS which contact the second blocking patterns BP2 and are separated from each other by the sacrificial patterns SP may be formed. The sacrificial layers SF may be replaced by the conductive layers CD, and the interlayer insulating layers IL and the sacrificial patterns SP may be removed to thereby form the air gaps AG each of which includes the first portion P1 and the second portion P2′.

Referring to FIG. 5C, the cell plug CPL may further include third blocking patterns BP3 in addition to the embodiments of FIG. 5B. Each of the third blocking patterns BP3 may be disposed between the first blocking patterns BP1. The third blocking patterns BP3 may couple the first blocking patterns BP1 which are separated from each other. The third blocking patterns BP3 may contact the first blocking patterns BP1 which are sequentially arranged in the Z direction. According to an embodiment, the third blocking patterns BP3 may contact the second blocking patterns BP2 which are sequentially arranged in the Z direction.

The third blocking patterns BP3 may surround second portions P2″ of the air gaps AG. The second portions P2″ may be defined by the third blocking patterns BP3. The first and second blocking patterns BP1 and BP2 might not be exposed to the air gaps AG by the third blocking patterns BP3. The third blocking patterns BP3 may include the same kind of material as the first and second blocking patterns BP1 and BP2. A fringing field of the conductive layers CD may be complemented by the third blocking patterns BP3.

The data storage patterns DS may contact the third blocking patterns BP3. The third blocking patterns BP3 may prevent the data storage patterns DS from coming into contact with the air gaps AG. The air gaps AG may be defined by the conductive layers CD and the third blocking patterns BP3.

Though not shown, after the manufacturing processes as described above with reference to FIG. 5B, the third blocking patterns BP3 may be formed in the air gaps AG. For example, the third blocking patterns BP3 may cover the cell plug CPL which is exposed through the air gaps AG.

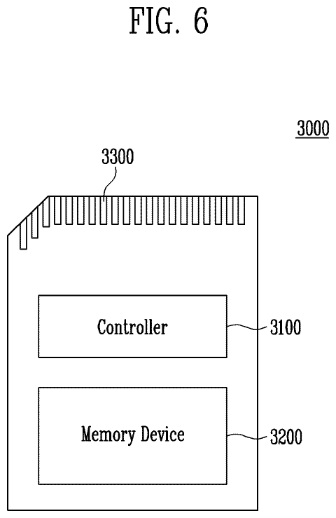

FIG. 6 is a diagram illustrating a memory card system 3000 to which a memory device according to an embodiment of the present disclosure is applied.

Referring to FIG. 6, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

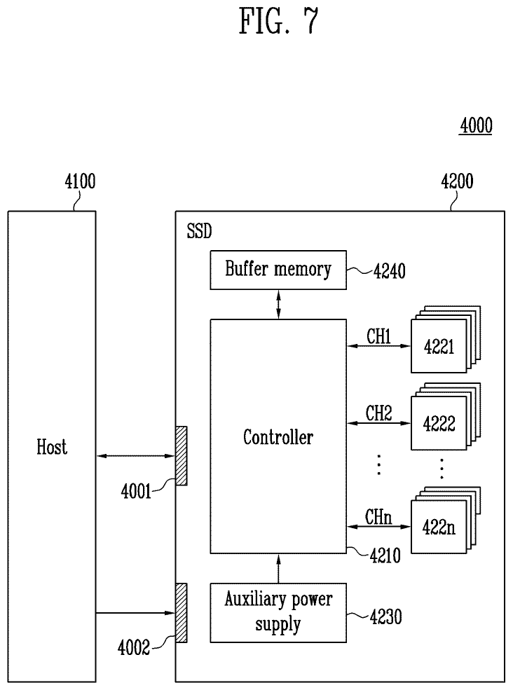

FIG. 7 is a diagram illustrating a solid state drive (SSD) system 4000 to which a memory device according to an embodiment of the present disclosure is applied.

Referring to FIG. 7, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to various embodiments of the present disclosure, operating performance of a memory device may be improved by reducing parasitic capacitance between conductive layers and parasitic capacitance between the conductive layers and a channel layer.

It will be apparent to those skilled in the art that various modifications can be made to the above-described examples of embodiments without departing from the spirit or scope of the disclosure. Thus, it is intended that the disclosure cover all such modifications provided they come within the scope of the appended claims and their equivalents.

What is claimed is:

1. A memory device, comprising:
a stacked structure including conductive layers spaced apart from each other in a first direction;
a cell plug located in the stacked structure and extending in the first direction; and
air gaps defined by the cell plug and conductive layers, the air gaps respectively located between the conductive layers,
wherein the air gaps extend past the conductive layers towards the cell plug in a second direction crossing the first direction.

2. The memory device of claim 1, wherein each of the air gaps comprises:
a first portion located between the conductive layers; and
a second portion extending from the first portion in the second direction towards the cell plug.

3. The memory device of claim 2, wherein the first portion is defined by an upper surface and a lower surface of the conductive layers, respectively.

4. The memory device of claim 2,
wherein a side surface of the cell plug includes concave surfaces, and
wherein the second portions are defined by the concave surfaces, respectively, of the cell plug.

5. The memory device of claim 1,
wherein the cell plug includes a blocking layer,
wherein the blocking layer comprises:
vertical portions contacting side surfaces of the conductive layers, respectively; and
concave portions curving inward toward a center of the cell plug, and
wherein each of the concave portions are respectively located between the conductive layers.

6. The memory device of claim 5, wherein the air gaps are respectively defined by the concave portions of the blocking layer.

7. The memory device of claim 1, wherein the cell plug includes data storage patterns spaced apart from each other in the first direction by the air gaps.

8. The memory device of claim 7, wherein at least a portion of each of the data storage patterns are located at the same level as the conductive layers, respectively.

9. The memory device of claim 1, wherein the cell plug comprises:
a channel layer passing through the conductive layers;
a tunneling layer surrounding the channel layer; and
a core pillar surrounded by the channel layer.

10. The memory device of claim 1, wherein the cell plug comprises:
a first blocking layer contacting side surfaces of the conductive layers; and
a second blocking layer contacting at least a portion of an inner surface of the first blocking layer.

11. The memory device of claim 10, wherein the second blocking layer extends on an inner surface of the first blocking layer between the air gaps.

12. The memory device of claim 10, wherein the cell plug further comprises data storage patterns surrounded by the second blocking layer.

13. The memory device of claim 1, wherein the cell plug comprises:
first blocking patterns contacting side surfaces of the conductive layers, respectively;
second blocking patterns contacting inner surfaces of the first blocking patterns, respectively; and
data storage patterns contacting inner surfaces of the second blocking patterns, respectively.

14. The memory device of claim 13, wherein the first blocking patterns and the data storage patterns are exposed by the air gaps.

15. The memory device of claim 13, wherein the first blocking patterns are separated from each other in the first direction by the air gaps, and
the second blocking patterns are separated from each other in the first direction by the air gaps.

16. The memory device of claim 13, wherein the data storage patterns are separated from each other in the first direction by the air gaps.

17. The memory device of claim 13, wherein the cell plug further comprises third blocking patterns disposed between the first blocking patterns.

18. The memory device of claim 17, wherein the air gaps are defined by the third blocking patterns, respectively.

19. The memory device of claim 17, wherein the third blocking patterns contact the first blocking patterns and the data storage patterns, respectively.

20. A method of manufacturing a memory device, the method comprising:
forming a stacked structure including sacrificial layers and interlayer insulating layers, wherein the sacrificial layers and the interlayer insulating layers are stacked alternately with each other in a first direction;
forming an opening extending in the first direction in the stacked structure;
forming sacrificial patterns on side surfaces of the interlayer insulating layers exposed through the opening;
forming a cell plug in the opening in which the sacrificial patterns are formed;
replacing the sacrificial layers with conductive layers; and
forming air gaps by removing the interlayer insulating layers and the sacrificial patterns.

21. The method of claim 20, wherein the forming of the cell plug comprises forming a blocking layer extending on the sacrificial layers and the sacrificial patterns, and
wherein the blocking layer includes vertical portions contacting the sacrificial layers, respectively, and concave portions contacting the sacrificial patterns, respectively.

22. The method of claim 21, wherein the forming of the cell plug further comprises forming data storage patterns contacting the vertical portions between the concave portions of the blocking layer.

23. The method of claim 22, wherein the forming of the cell plug further comprises:
forming a tunneling layer contacting the blocking layer and the data storage patterns;
forming a channel layer on an inner surface of the tunneling layer; and
forming a core pillar surrounded by the channel layer.

24. The method of claim 20, wherein in the forming of the air gaps, each of the air gaps includes first portions located between the conductive layers and second portions extending the first portions towards the cell plug.

25. The method of claim 20, wherein the forming of the cell plug comprises:
forming a first blocking layer extending on the sacrificial layers and the sacrificial patterns; and
forming a second blocking layer contacting at least a portion of an inner surface of the first blocking layer.

26. The method of claim 20, wherein the forming of the cell plug comprises:
forming a first blocking layer extending on the sacrificial layers and the sacrificial patterns;
forming first blocking patterns by removing a portion of the first blocking layer located on the sacrificial patterns;
forming a second blocking layer on the sacrificial patterns and the first blocking patterns; and
forming second blocking patterns by removing a portion of the second blocking layer located on the sacrificial patterns.

27. The method of claim 26, wherein the forming of the cell plug comprises forming data storage patterns contacting the second blocking patterns, respectively, and spaced apart from each other by the sacrificial patterns.

28. The method of claim 27, further comprising, after the forming of the air gaps: forming third blocking patterns contacting the first blocking patterns and the data storage patterns that were exposed through the air gaps.
